(19) United States
(12) Patent Application Publication
(10) Pub. No.: US 2025/0098385 A1
(43) Pub. Date: Mar. 20, 2025

(54) ELECTRONIC DEVICE

(71) Applicant: Innolux Corporation, Miaoli County (TW)

(72) Inventors: Yuan-Lin Wu, Miaoli County (TW); Jia-Yuan Chen, Miaoli County (TW); Tsung-Han Tsai, Miaoli County (TW); Kuan-Feng Lee, Miaoli County (TW)

(73) Assignee: Innolux Corporation, Miaoli County (TW)

(21) Appl. No.: 18/804,136

(22) Filed: Aug. 14, 2024

(30) Foreign Application Priority Data
Sep. 20, 2023 (CN) 202311215938.0

(51) Int. Cl. H01L 33/62; H01L 25/075; H01L 25/16

(52) U.S. Cl. CPC H10H 20/857; H01L 25/0753; H01L 25/167

(57) ABSTRACT

An electronic device including a flexible substrate, a plurality of electronic components, and a first driving unit is provided. The flexible substrate includes a surface having a first region and a second region. The first region has a Gaussian curvature of 0 and the second region has a non-zero Gaussian curvature. The plurality of electronic components are disposed on the flexible substrate. The first driving unit is disposed on the first region of the flexible substrate. One of the plurality of electronic components located on the second region of the flexible substrate is driven by the first driving unit.

### CROSS-REFERENCE TO RELATED APPLICATION

This application claims the priority benefit of China application serial no. 202311215938.0, filed on Sep. 20, 2023. The entirety of the above-mentioned patent application is hereby incorporated by reference herein and made a part of this specification.

### BACKGROUND

### Technical Field

The disclosure relates to an electronic device, and particularly relates to a flexible electronic device.

### Description of Related Art

In order to increase the screen-to-body ratio of existing electronic devices, it is common to dispose electronic components (such as display elements/sensing elements/color filter patterns and/or micro-light-emitting diodes) and driving components on the side surfaces of the electronic devices. However, when driving components are disposed on a surface having a Gaussian curvature that is not equal to 0, electrical abnormalities are likely to occur and/or driving components may fall off from the surface of the electronic device, which reduces the reliability of the electronic device.

### SUMMARY

Some embodiments of the disclosure are directed to an electronic device that has relatively good reliability.

An electronic device provided according to some embodiments of the disclosure includes a flexible substrate, a plurality of electronic components, and a first driving unit. The flexible substrate includes a surface having a first region and a second region. The first region has a Gaussian curvature that is equal to 0, and the second region has a Gaussian curvature that is not equal to 0. The plurality of electronic components are disposed on the flexible substrate. The first driving unit is disposed on the first region of the flexible substrate. One of the plurality of electronic components located on the second region of the flexible substrate is driven by the first driving unit.

An electronic device provided according to other embodiments of the disclosure includes a flexible substrate, a first connection pad, a plurality of electronic components, and a first integrated circuit unit. The flexible substrate includes a corner region and a non-corner region. The corner region has an arc-shaped edge in a top view of the electronic device. The first connection pad overlaps the flexible substrate. The plurality of electronic components are disposed on the flexible substrate. The first integrated circuit unit is bonded to the first connection pad and disposed on the non-corner region of the flexible substrate. One of the plurality of electronic components located on the corner region of the flexible substrate is driven by the first integrated circuit unit.

To make the above-mentioned features and advantages of the disclosure easier to understand, exemplary embodiments will be described in detail hereinafter with reference to the accompanying drawings.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a partial top view of the electronic device according to an embodiment of the disclosure.

FIG. 1B is a perspective view of the electronic device according to an embodiment of the disclosure.

FIG. 2 is a partial cross-sectional view of the electronic device according to the first embodiment of the disclosure.

FIG. 3 is a partial cross-sectional view of the electronic device according to the second embodiment of the disclosure.

FIG. 4 is a partial cross-sectional view of the electronic device according to the third embodiment of the disclosure.

FIG. 5 is a partial cross-sectional view of the electronic device according to the fourth embodiment of the disclosure.

FIG. 6 is a partial top view of the electronic device according to another embodiment of the disclosure.

FIG. 7A is a partial cross-sectional view of the chip packaging structure of the microchip unit according to an embodiment of the disclosure.

FIG. 7B is a partial cross-sectional view of the chip packaging structure of the microchip unit according to another embodiment of the disclosure.

FIG. 7C is a partial cross-sectional view of the chip packaging structure of the microchip unit according to yet another embodiment of the disclosure.

FIG. 8A to FIG. 8D are schematic views of the regions having different Gaussian curvatures on the curved surface of the flexible substrate included in the electronic device according to an embodiment of the disclosure.

### DETAILED DESCRIPTION OF DISCLOSED EMBODIMENTS

Reference will now be made in detail to the exemplary embodiments of the disclosure, and examples of the exemplary embodiments are illustrated in the accompanying drawings. Whenever possible, the same reference numbers are used in the drawings and descriptions to indicate the same or similar parts.

The disclosure may be understood by referring to the following detailed description in conjunction with the accompanying drawings. It should be noted that, for easy understanding of the readers and simplicity of the drawings, many of the drawings in this disclosure merely depict a part of the electronic device, and specific components in the drawings may not be drawn according to actual scale. In addition, the number and size of components in the drawings are merely for illustration and are not intended to limit the scope of the disclosure.

Certain terminologies throughout the description and the following claims serve to refer to specific components. As will be understood by those skilled in the art, electronic device manufacturers may denote components by different names. It is not intended to distinguish the components that differ by name but not by function. In the following specification and claims, the terminologies “including,” “comprising,” “having,” etc. are open-ended terminologies, so they should be interpreted to mean “including but not limited to . . . ” Therefore, when the terminologies “including,” “comprising,” and/or “having” are used in the description of the disclosure, they specify the presence of corresponding features, regions, steps, operations, and/or components, but do not exclude the presence of one or more corresponding features, regions, steps, operations, and/or components.

The directional terminologies mentioned in the disclosure, such as “upper,” “lower,” “front,” “rear,” “left,” “right” and so on, are used with reference to the accompanying drawings. Therefore, the directional terminologies used are for illustrative but not restrictive purposes in the disclosure. In the accompanying drawings, each drawing shows the general features of the methods, structures and/or materials adopted in a specific embodiment. However, the drawings should not be construed as defining or limiting the scope or nature covered by the embodiments. For example, for clarity, the relative size, thickness, and position of each layer, region, and/or structure may be reduced or enlarged.

When a component (for example, layer or region) is referred to as being “located on another component,” it may mean that the component is directly located on another component, or it may mean that there is an intermediary component between the two components. On the other hand, when a component is referred to as being “located directly on another component,” unless otherwise specified in the specification, there is no intermediary component between the two components. In addition, when a component is referred to as being “located on another component,” the two components have a top-down relationship in the direction of a top view, and the component may be located above or under another component. This top-down relationship depends on the orientation of the device.

The terminologies “equal,” “identical,” “substantially,” or “approximately” are generally interpreted as being within 20% of a given value or range, or interpreted as being within 10%, 5%, 3%, 2%, 1%, or 0.5% of a given value or range.

The ordinal numbers used in the specification and claims, such as the terminologies “first,” “second,” and the like, to qualify a component do not imply or represent that the component or components are preceded with any ordinal numbers, nor do they represent the order of a certain component and another component, or the order in the manufacturing method, and are used merely to clearly distinguish a component with one name from another component with the same name. Different terminologies may be used in the claims and the specification, and accordingly, a first component in the specification may be a second component in the claims.

Note that in the following embodiments, the technical features provided in several different embodiments may be replaced, reorganized, and mixed without departing from the spirit of the disclosure so as to complete other embodiments. The technical features of the embodiments may be mixed and matched arbitrarily as long as they do not violate the spirit of the disclosure or conflict with each other.

The electrical connection or coupling described in this disclosure may refer to direct connection or indirect connection. In the case of direct connection, the endpoints of the components on the two circuits are directly connected or are connected to each other by a conductor segment. In the case of indirect connection, between the end points of the components on the two circuits there are switches, diodes, capacitors, inductances, other suitable components, or a combination of the above-mentioned components, but the disclosure is not limited thereto.

In the disclosure, thickness, length, width, and area may be measured by an optical microscope (OM), and thickness may be measured by a cross-sectional image in an electron microscope, but the disclosure is not limited thereto. Moreover, any two values or directions used for comparison may have certain errors. If a first value is equal to a second value, it implies that there may be an error of about 10% between the first value and the second value. If a first direction is perpendicular to a second direction, the angle between the first direction and the second direction may be between 80 degrees and 100 degrees. If the first direction is parallel to the second direction, the angle between the first direction and the second direction may be between 0 degrees and 10 degrees.

The electronic device disclosed herein may be applied to a display device, a light-emitting device, a backlight device, an antenna device, a sensing device, a tiled device, or a temporary storage substrate used to assist electronic units to be placed at a specific pitch, but is not limited thereto. The electronic device may be a bendable or flexible electronic device. The display device may be a non-self-luminous display device or a self-luminous display device. The antenna device may be a liquid crystal antenna device or a non-liquid crystal antenna device, and the sensing device may be a sensing device for sensing capacitance, light, heat, or ultrasonic waves, but is not limited thereto. The electronic device may include passive components and active components, such as capacitors, resistors, inductors, diodes, transistors, and the like. The diodes may include light-emitting diodes or photodiodes. The light-emitting diodes (LED) may include, for example, organic light-emitting diodes (OLED), sub-millimeter light-emitting diodes (mini LED), micro light-emitting diodes (micro LED), or quantum dot light-emitting diodes (quantum dot LED), but is not limited thereto. The tiled device may be, for example, a display tiled device or an antenna tiled device, but is not limited thereto. It should be noted that the electronic device may be any arrangement and combination of the foregoing, but not limited to thereto. In addition, the appearance of the electronic device may be rectangular, circular, polygonal, in a shape with curved edges, or in other suitable shapes.

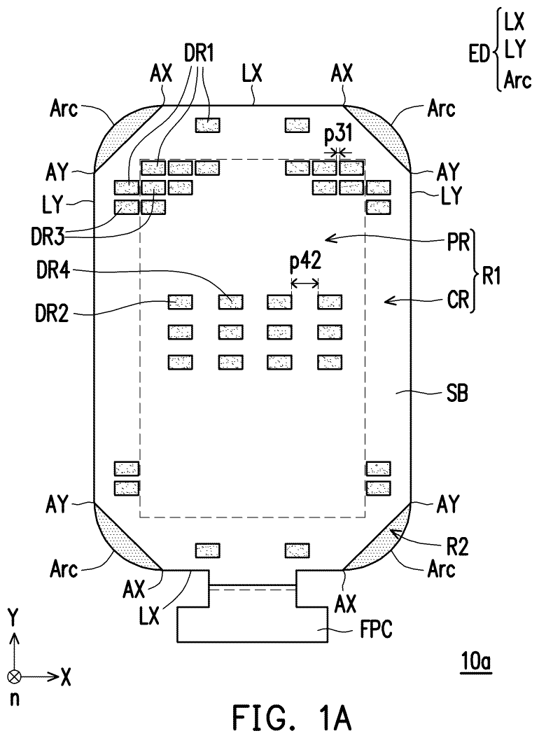

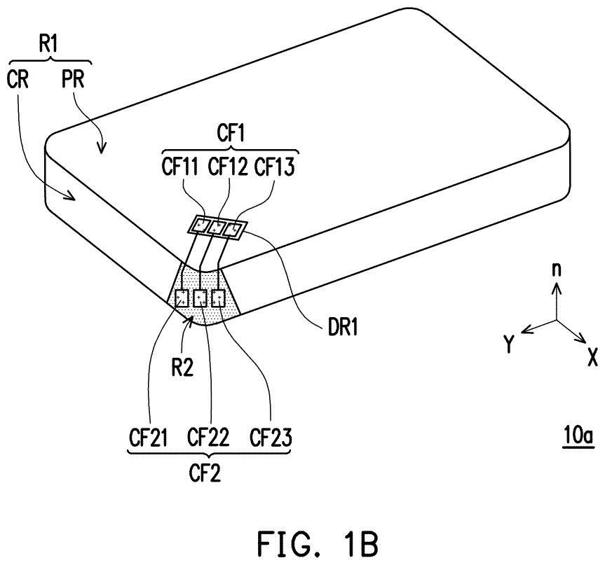

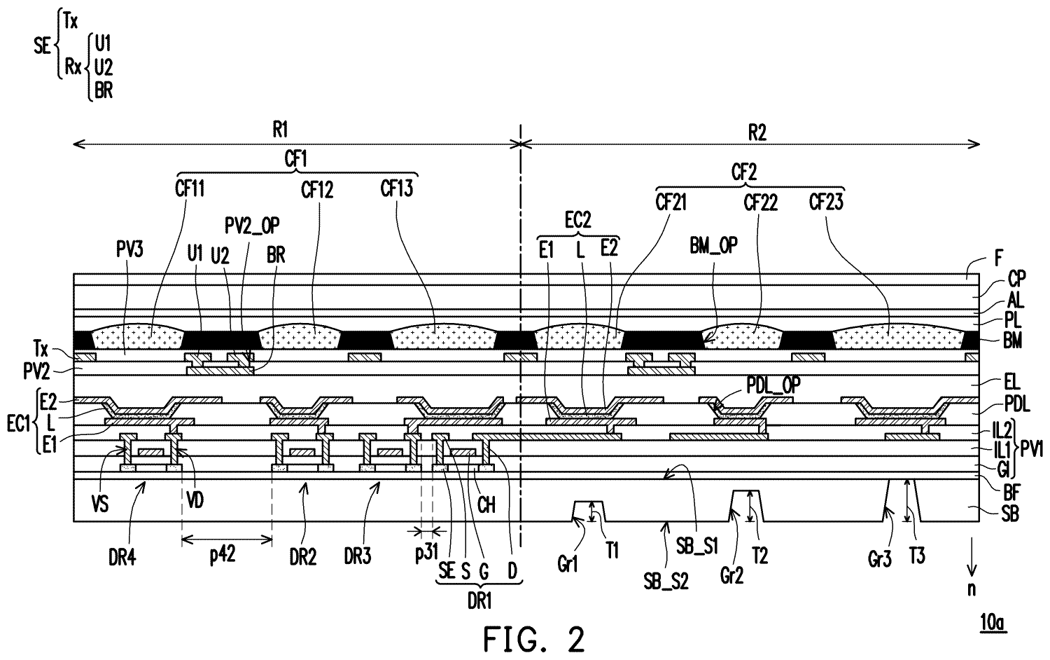

FIG. 1A is a partial top view of the electronic device according to an embodiment of the disclosure FIG. 1B is a perspective view of the electronic device according to an embodiment of the disclosure. FIG. 2 is a partial cross-sectional view of the electronic device according to the first embodiment of the disclosure.

Referring to FIG. 1A, FIG. 1B, and FIG. 2, an electronic device 10a of this embodiment includes a flexible substrate SB, a plurality of electronic components EC, and a first driving unit DR1. In this embodiment, the electronic device 10a may be a display device having a touch function, but the disclosure is not limited thereto.

The material of the flexible substrate SB includes, for example, plastic. For example, the material of the flexible substrate SB may include polymethyl methacrylate (PMMA), polycarbonate (PC), polyimide (PI), polyethylene terephthalate (PET), other suitable materials, or a combination of the aforementioned materials, but the disclosure is not limited thereto. In other embodiments, the material of the flexible substrate SB may include non-metal oxide (such as silicon oxide but not limited thereto), adhesive and/or a metal layer having a support function. The flexible substrate SB may include, for example, a single-layer structure or a multi-layer structure. When the flexible substrate SB includes a multi-layer structure, the material of the flexible substrate SB may include a combination of the aforementioned materials, but the disclosure is not limited thereto.

In some embodiments, the flexible substrate SB includes a surface SB_S1 having a first region R1 and a second region R2. The Gaussian curvature of the first region R1 is equal to 0 and the Gaussian curvature of the second region R2 is not equal to 0. It is worth noting that the surface SB_S1, which has a Gaussian curvature, of the flexible substrate SB may be measured by measuring components other than the flexible substrate SB in the electronic device 10a. That is, the Gaussian curvatures of the first region R1 and the second region R2 may be obtained by measuring the Gaussian curvature of a cover plate CP which will be described later. The Gaussian curvature referred to in this embodiment may be the product of two main curvatures extending from a point at any position on a curved surface along the curved surface. More specifically, a point on a curved surface can extend out an infinite number of curves in all directions of the curved surface, and each curve has its own curvature. The main curvature described here is defined as follows. Among the infinite number of curvatures, there is a curvature maximum value, and the curvature of the curve perpendicular to the curve of the maximum value (Max) is the minimum value (Min) of the infinite number of curvatures. Then, the curve of the curvature maximum value and the curve of the curvature minimum value are two main curvatures of this point.

This embodiment provides two methods for determining the Gaussian curvature, which may scan and model a target curved surface using scanning equipment and 3D analysis software (such as Design X 3D) to analyze and obtain objective Gaussian curvature values, but the disclosure is not limited thereto.

The first method provided in this embodiment is to randomly connect three non-collinear points on a curved surface to form a triangle, and then determine whether the sum of the interior angles of the triangle is greater than 180 degrees, equal to 180 degrees, or less than 180 degrees. For example, when the Gaussian curvature of the curved surface is positive, and any three points on the curved surface are connected to form a triangle, the sum of the interior angles of the triangle is greater than 180 degrees. When the Gaussian curvature of the curved surface is negative, and any three points on the curved surface are connected to form a triangle, the sum of the interior angles of the triangle is less than 180 degrees. For example, when the Gaussian curvature of the curved surface is 0, and any three points on the curved surface are connected to form a triangle, the sum of the interior angles of the triangle is equal to 180 degrees. It is worth noting that when the sum of the interior angles of the triangle is equal to 180 degrees, within an error range of plus or minus 5 degrees, it is considered as having a Gaussian curvature of 0.

The second method provided in this embodiment is to randomly pick a point on the curved surface, wherein there are two mutually perpendicular direction vectors at this point, and the two direction vectors respectively have a first curvature and a second curvature. Then, the Gaussian curvature of the curved surface is the product of the first curvature and the second curvature. For example, when the Gaussian curvature of the curved surface is positive, the first curvature and the second curvature of the two direction vectors may both be positive. When the Gaussian curvature of the curved surface is negative, one of the first curvature and the second curvature of the two direction vectors is negative and the other is positive. When the Gaussian curvature of the curved surface is 0, at least one of the first curvature and the second curvature of the two direction vectors is 0.

In this embodiment, the first region R1 of the flexible substrate SB includes a flat portion PR and a curved portion CR. The flat portion PR referred to in this embodiment is a region that cannot be bent when the electronic device 10a is used, and the curved portion CR referred to in this embodiment is a region that can be bent when the electronic device 10a is used or that is curved relative to the flat portion PR after the electronic device 10a is formed. The flat portion PR is, for example, located approximately in the middle region of the electronic device 10a, and the curved portion CR is, for example, located on at least one side of the flat portion PR. In this embodiment, the curved portion CR is located on four sides of the flat portion PR. In this embodiment, the curved portion CR connects the flat portion PR and the second region R2. In detail, the second region R2 may be located, for example, at four corners of the electronic device 10a, and may be connected to the flat portion PR, for example, through curved portions CR located on four sides of the flat portion PR. Accordingly, the second region R2 may be regarded as a corner region of the electronic device 10a, and the first region R1 may be regarded as a non-corner region of the electronic device 10a relative to the second region R2. The corner region referred to in this embodiment is a region with an arc-shaped edge, and the non-corner region referred to in this embodiment is a region with a straight edge. In detail, as shown in FIG. 1A, an edge ED of the flexible substrate SB includes a straight edge LX, a straight edge LY, and an arc-shaped edge Arc. The straight edge LX extends, for example, in the direction X, and the straight edge LY extends, for example, in the direction Y. Two ends of the arc-shaped edge Arc respectively connect, for example, one end of the straight edge LX and one end of the straight edge LY. The connection point between the arc-shaped edge Arc and the straight edge LX is AX, and the connection point between the arc-shaped edge Arc and the straight edge LY is AY. It is worth noting that the arc-shaped edge Arc may be defined as, for example, a case where the curvature of the edge ED of the flexible substrate SB is not 0, and the straight edge LX and the straight edge LY may be defined as, for example, a case where the curvature of the edge ED of the flexible substrate SB is 0, but the disclosure is not limited thereto.

The plurality of electronic components EC are disposed on the flexible substrate SB, for example. In some embodiments, the electronic components EC may include a chip, a light-emitting diode, a variable capacitor, a variable resistor, a varactor diode, other suitable electronic components, or a combination of the aforementioned, but the disclosure is not limited thereto. In this embodiment, one of the plurality of electronic components EC includes a light-emitting unit. The light-emitting unit may include an organic light-emitting diode or an inorganic light-emitting diode. In detail, the electronic component EC may include, for example, a first electrode E1, a light-emitting layer L, and a second electrode E2.

The first electrode E1 is, for example, disposed on the flexible substrate SB. In some embodiments, the first electrode E1 may be used as the anode of the electronic component EC, but the disclosure is not limited thereto. The material of the first electrode E1 may include metal, metal oxide, other suitable materials, or a combination of the aforementioned, but the disclosure is not limited thereto.

The light-emitting layer L is, for example, disposed on the first electrode E1. In some embodiments, the light-emitting layer L may include a suitable organic material or inorganic material, but the disclosure is not limited thereto.

For example, in some embodiments, the electronic component EC may further include a first semiconductor layer (not shown) and a second semiconductor layer (not shown). The first semiconductor layer is electrically connected to the first electrode E1, and the second semiconductor layer is electrically connected to the second electrode E2.

The first semiconductor layer and the second semiconductor layer may respectively include an N-type doped semiconductor and a P-type doped semiconductor, or may respectively include a P-type doped semiconductor and an N-type doped semiconductor. The materials of the first semiconductor layer and the second semiconductor layer may include, for example, gallium nitride (GaN), indium gallium nitride (InGaN), gallium arsenide (GaAs), aluminum gallium indium phosphide (AlGaInP), other materials composed of Group IIIA and Group VA elements, or other suitable materials, but the disclosure is not limited thereto. The light-emitting layer L may, for example, have a quantum well (QW), which may be, for example, a single quantum well (SQW), a multiple quantum well (MQW), or other quantum wells. Accordingly, the holes and electrons provided by the first semiconductor layer and the second semiconductor layer may be combined in the light-emitting layer L to emit light energy.

The second electrode E2 is, for example, disposed on the light-emitting layer L. In some embodiments, the second electrode E2 may be used as the cathode of the electronic component EC, but the disclosure is not limited thereto. The material of the second electrode E2 may include metal, metal oxide, other suitable materials, or a combination of the aforementioned, and the disclosure is not limited thereto.

In some embodiments, although not shown in the drawings, the pitch between two adjacent electronic components EC1 of the plurality of electronic components EC located on the first region R1 may be smaller than the pitch between two adjacent electronic components EC2 of the plurality of electronic components EC located on the second region R2. In detail, considering that the resolution in the second region R2 (the corner region of the electronic device 10a) may be less than the resolution in the first region R1, the pitch between two adjacent electronic components EC2 located on the second region R2 may be greater than the pitch between two adjacent electronic components EC1 located on the first region R1. The “adjacent” mentioned here may, for example, mean that there is no identical or similar electronic component therebetween. It is worth noting that the “pitch” mentioned here may be, for example, the shortest distance between adjacent electronic components, and the shortest distance is measured from the respective edges of the adjacent electronic components, but the disclosure is not limited thereto. From another perspective, the density of the electronic components EC2 located on the second region R2 may, for example, be less than the density of the electronic components EC1 located on the first region R1. That is, the number of electronic components EC2 in the same cross-sectional area of the second region R2 is, for example, smaller than the number of electronic components EC1 in the same cross-sectional area of the first region R1.

The first driving unit DR1 is, for example, disposed on the first region R1 of the flexible substrate SB. The first driving unit DR1 may, for example, be disposed on the flat portion PR and/or the curved portion CR of the first region R1. In detail, in some embodiments, the first driving unit DR1 may be disposed merely on the flat portion PR of the first region R1. In other embodiments, the first driving unit DR1 may be disposed merely on the curved portion CR of the first region R1. In this embodiment, the first driving unit DR1 is disposed on the flat portion PR and the curved portion CR of the first region R1, as shown in FIG. 1A.

In this embodiment, the first driving unit DR1 includes a transistor. In detail, the first driving unit DR1 may include, for example, a gate G, a source S, a drain D, and a semiconductor layer SE, but the disclosure is not limited thereto. The gate G partially overlaps the semiconductor layer SE in a top view direction n of the substrate SB, for example. The region where the semiconductor layer SE overlaps the gate G may be regarded as a channel region CH, and the semiconductor layer SE may have a source region and a drain region located on opposite sides of the channel region. The source S and the drain D are, for example, separated from each other, and each is electrically connected to the semiconductor layer SE. In some embodiments, the material of the semiconductor layer SE may include amorphous silicon, low temperature polycrystalline silicon (LTPS), metal oxide, other suitable materials, or a combination of the aforementioned. In this embodiment, the material of the semiconductor layer SE includes low temperature polycrystalline silicon, but the disclosure is not limited thereto. In other embodiments, the semiconductor layer SE of the first driving unit DR1 may include a combination of low temperature polycrystalline silicon and metal oxide, that is, low temperature polysilicon oxide (LTPO). In this embodiment, the source S and the drain D may be electrically connected to the source region and the drain region of the semiconductor layer SE through a hole VS and a hole VD, respectively, but the disclosure is not limited thereto. The first driving unit DR1 in this embodiment is, for example, a top gate thin film transistor. Although this embodiment illustrates a top gate thin film transistor as an example, the disclosure is not limited thereto.

In this embodiment, the electronic device 10a further includes a second driving unit DR2. The second driving unit DR2 is, for example, disposed on the first region R1 of the flexible substrate SB, and the second driving unit DR2 is, for example, disposed on the flat portion PR of the first region R1. In this embodiment, the first driving unit DR1 is closer to the curved portion CR than the second driving unit DR2. In detail, the second driving unit DR2 is, for example, disposed approximately on the middle region of the flat portion PR, and the first driving unit DR1 is, for example, disposed approximately on the edge region of the flat portion PR, but the disclosure is not limited thereto. In this embodiment, the second driving unit DR2 includes a transistor. That is, the second driving unit DR2 may, for example, have the same or similar structure as the first driving unit DR1, but the disclosure is not limited thereto. In other embodiments, the second driving unit DR2 may have a different structure from the first driving unit DR1. For example, the semiconductor layer of the second driving unit DR2 may include low temperature polysilicon oxide (LTPO) while the semiconductor layer SE of the first driving unit DR1 may include metal oxide (for example, indium gallium zinc oxide (IGZO)).

In this embodiment, the electronic device 10a further includes a third driving unit DR3 and a fourth driving unit DR4. The third driving unit DR3 and the fourth driving unit DR4 are, for example, disposed on the first region R1 of the flexible substrate SB. In some embodiments, the third driving unit DR3 is adjacent to the first driving unit DR1. That is, the third driving unit DR3 may, for example, be disposed on the flat portion PR and/or the curved portion CR of the first region R1. In some embodiments, the fourth driving unit DR4 is adjacent to the second driving unit DR2. That is, the fourth driving unit DR4 may be disposed on the flat portion PR of the first region R1, for example. In this embodiment, the third driving unit DR3 and the fourth driving unit DR4 include transistors. That is to say, the third driving unit DR3 and the fourth driving unit DR4 may have the same or similar structures as the first driving unit DR1, for example, but the disclosure is not limited thereto.

In this embodiment, the driving unit DR (including the first driving unit DR1, the second driving unit DR2, the third driving unit DR3, and the fourth driving unit DR4) is not disposed on the second region R2 (having a Gaussian curvature that is not equal to 0) of the flexible substrate SB. That is, the driving unit DR is disposed on the first region R1 (having a Gaussian curvature that is equal to 0) of the flexible substrate SB. Accordingly, when the electronic device 10a is bent, electrical abnormalities of the driving unit DR resulting from bending may be reduced, thereby improving the reliability of the electronic device 10a.

In this embodiment, since the driving unit DR (including the first driving unit DR1, the second driving unit DR2, the third driving unit DR3, and the fourth driving unit DR4) is not disposed on the second region R2 (having a Gaussian curvature that is not equal to 0) of the flexible substrate SB, more driving units are disposed on the region close to the second region R2 in the first region R1, making it possible to drive the electronic components EC2 located on the second region R2 through these driving units. For example, one of the plurality of electronic components EC2 located on the second region R2 of the flexible substrate SB may be driven by the first driving unit DR1 located on the first region R1 of the flexible substrate SB, and the electronic component EC2 may be driven by the first driving unit DR1 located on the flat portion PR and/or driven by the first driving unit DR1 located on the curved portion CR. Accordingly, in this embodiment, the pitch p42 between the fourth driving unit DR4 and the second driving unit DR2 located on the first region R1 is greater than the pitch p31 between the third driving unit DR3 and the first driving unit DR1 located on the first region R1. It is worth noting that the “pitch” mentioned here may be, for example, the shortest distance between adjacent driving units, and the shortest distance is measured from the respective edges of the adjacent driving units, but the disclosure is not limited thereto. From another perspective, the density of the driving units (the first driving unit DR1 and the third driving unit DR3) disposed on the edge region of the first region R1 is greater than the density of the driving units (the second driving unit DR2 and the fourth driving unit DR4) disposed on the middle region of the first region R1. That is, the number of the first driving unit DR1 and the third driving unit DR3 in the same cross-sectional area of the first region R1 is greater than the number of the second driving unit DR2 and the fourth driving unit DR4 in the same cross-sectional area of the first region R1.

A flexible circuit board FPC is disposed on at least one side of the surface SB_S1 of the flexible substrate SB in a top view of the electronic device 10a, for example. In some embodiments, the flexible circuit board FPC may be joined to the curved portion CR of the first region R1 through conductive glue (not shown), but the disclosure is not limited thereto. In some embodiments, the flexible circuit board FPC may include electrodes and/or wiring for use in the electronic device 10a. For example, the flexible circuit board FPC may include a timing control circuit, a data driving circuit, a voltage supply circuit, a power driving circuit, other suitable circuits, or a combination thereof, but the disclosure is not limited thereto.

In some embodiments, the electronic device 10a may further include a buffer layer BF, an insulating layer PV1, a pixel definition layer PDL, an encapsulation layer EL, a sensing structure SE, a light shielding structure BM, a color filter pattern CF, a flat layer PL, an adhesive layer AL, a cover plate CP, and a functional layer F.

The buffer layer BF is disposed on the substrate SB, for example. The buffer layer BF may have, for example, relatively good bonding properties with subsequent film layers formed thereon, but the disclosure is not limited thereto. The material of the buffer layer BF may be, for example, an inorganic material (such as silicon oxide, silicon nitride, silicon oxynitride, or a stacked layer of at least two of the aforementioned materials). In some embodiments, the buffer layer BF may have a single-layer structure or a multi-layer structure, but the disclosure is not limited thereto.

The insulating layer PV1 is disposed on the substrate SB, for example. In this embodiment, the insulating layer PV1 may have a multi-layer structure, and may be used to separate different conductive layers in the driving unit DR. In detail, taking the first driving unit DR1 among the driving units DR as an example, the insulating layer PV1 may include an insulating layer GI, an insulating layer IL1, and an insulating layer IL2. The insulating layer GI is disposed between the semiconductor SE and the gate G of the first driving unit DR1, the insulating layer IL1 is disposed between the source S (or the drain D) and the gate G of the first driving unit DR1, and the insulating layer IL2 covers the source S and the drain D of the first driving unit DR1. The material of the insulating layer PV1 may be, for example, an inorganic material (such as silicon oxide, silicon nitride, silicon oxynitride, or a stacked layer of at least two of the aforementioned materials), but the disclosure is not limited thereto.

The pixel definition layer PDL is, for example, disposed on the insulating layer PV1. In this embodiment, the pixel definition layer PDL partially covers the first electrode E1. From another perspective, the pixel definition layer PDL includes, for example, an opening PDL_OP that exposes a portion of the first electrode E1. The light-emitting layer L may, for example, be disposed in the opening PDL_OP, but the disclosure is not limited thereto. The pixel definition layer PDL may include, for example, a transparent material or a light shielding material, but the disclosure is not limited thereto.

The encapsulation layer EL is, for example, disposed on a plurality of electronic components EC. In this embodiment, the encapsulation layer EL covers a plurality of electronic components EC. In some embodiments, the encapsulation layer EL may have a single-layer structure or a multi-layer structure, but the disclosure is not limited thereto. The material of the encapsulation layer EL may be, for example, an inorganic material (such as silicon oxide, silicon nitride, silicon oxynitride, or a stacked layer of at least two of the aforementioned materials), an organic material (such as polytetrafluoroethylene, polyimide, parylene, benzocyclobutene, or other suitable materials), or a combination of the aforementioned, but the disclosure is not limited thereto. For example, the encapsulation layer EL may be a stacked structure of inorganic material/organic material/inorganic material, but the disclosure is not limited thereto. In this embodiment, the encapsulation layer EL may have a relatively flat top surface, so that subsequent film layers formed thereon have a relatively good yield.

The sensing structure SE is, for example, disposed on the encapsulation layer EL, and includes, for example, a first unit U1, a second unit U2, and a bridge portion BR. In some embodiments, the sensing structure SE may be used to sense the finger of a user, a stylus, and a suitable external object, but the disclosure is not limited thereto. The first unit U1 and the second unit U2 are, for example, disposed on the encapsulation layer EL. In this embodiment, the first unit U1, the second unit U2, and the bridge portion BR may be, for example, a sensing electrode Rx of the sensing structure SE. In detail, the conductive layer in the sensing structure SE may include the sensing electrode Rx and a driving electrode Tx. The sensing electrode Rx and the driving electrode Tx may, for example, have a diamond shape and/or a metal mesh shape in the top view direction n of the flexible substrate SB, but the disclosure is not limited thereto. In other embodiments, the first unit U1, the second unit U2, and the bridge portion BR may be the driving electrode of the sensing structure SE. In some embodiments, the electronic device 10a further includes an insulating layer PV2. The insulating layer PV2 is, for example, disposed on the encapsulation layer EL and has an opening PV2_OP that exposes the first unit U1 and the second unit U2. The bridge portion BR is, for example, disposed on the insulating layer PV2 and connected to the first unit U1 and the second unit U2. In this embodiment, the bridge portion BR belongs to different layers from the first unit U1 and the second unit U2, and may be electrically connected to the first unit U1 and the second unit U2 through the opening PV2_OP penetrating the insulating layer PV2. In some embodiments, the electronic device 10a further includes an insulating layer PV3. The insulating layer PV3 is, for example, disposed on the insulating layer PV2 and covers the bridge portion BR. In some embodiments, the materials of the sensing electrode Rx and the driving electrode Tx may include a transparent conductive material or a metal material, and the materials of the insulating layer PV2 and the insulating layer PV3 may include an inorganic material (such as silicon oxide, silicon nitride, silicon oxynitride, or a stacked layer of at least two of the aforementioned materials), but the disclosure is not limited thereto.

The light shielding structure BM is, for example, disposed on the sensing structure SE, and includes, for example, an opening BM_OP. The opening BM_OP of the light shielding structure BM may expose a portion of the insulating layer PV3 of the sensing structure SE. In some embodiments, the light shielding structure BM may include a single-layer structure or a multi-layer structure, but the disclosure is not limited thereto. In some embodiments, the light shielding structure BM may include a light shielding material. For example, the material of the light shielding structure BM may include black resin or a metal material with low reflectivity, but the disclosure is not limited thereto.

The color filter pattern CF is, for example, disposed on the sensing structure SE, and is disposed, for example, in the opening BM_OP of the light shielding structure BM, but the disclosure is not limited thereto. In other embodiments, a wavelength conversion pattern (not shown) may be disposed in the opening BM_OP of the light shielding structure BM instead of or together with the color filter pattern CF. The material of the wavelength conversion pattern may, for example, include a phosphor material, a fluorescent material, quantum dot particles, or other optical conversion materials that can convert the color of light, and the aforementioned optical conversion materials may be arranged and combined in any manner, and the disclosure is not limited thereto. In some embodiments, the color filter pattern CF may include a red filter pattern, a green filter pattern, or a blue filter pattern, but the disclosure is not limited thereto. In this embodiment, the color filter pattern CF may include a color filter pattern CF1 disposed in the first region R1 and a color filter pattern CF2 disposed in the second region R2. The color filter pattern CF1 may include a color filter unit CF11, a color filter unit CF12, and a color filter unit CF13, and the color filter pattern CF2 may include a color filter unit CF21, a color filter unit CF22, and a color filter unit CF23. The color filter unit CF11, the color filter unit CF12, and the third color filter unit CF13 may be different from each other, and the color filter unit CF21, the color filter unit CF22, and the third color filter unit CF23 may be different from each other, but the disclosure is not limited thereto.

The flat layer PL is, for example, disposed on the insulating layer PV3 and covers the light shielding structure BM and the color filter pattern CF. The material of the flat layer PL may be, for example, an organic material (such as polytetrafluoroethylene, polyimide, parylene, benzocyclobutene, or other suitable materials), but the disclosure is not limited thereto. In this embodiment, the flat layer PL may have a relatively flat top surface, so that subsequent film layers formed thereon have a relatively good yield.

The adhesive layer AL is, for example, disposed on the flat layer PL. The material of the adhesive layer AL may include optical clear resin (OCR) or optical clear adhesive (OCA) and, for example, includes acrylic resin, silicone resin, epoxy resin, other suitable materials, or a combination of the aforementioned materials, but the disclosure is not limited thereto.

The cover plate CP is, for example, disposed on the flat layer PL, and the cover plate CP may be bonded to the flat layer PL, for example, through the adhesive layer AL. The material of the cover plate CP may include, for example, glass, plastic, or a combination thereof. In this embodiment, the material of the cover plate CP includes plastic, but the disclosure is not limited thereto.

The functional layer F is disposed on the cover plate CP, for example. In some embodiments, the functional layer F may include a material with high hardness properties. For example, the functional layer F may include a hard coating layer with a pencil hardness greater than 5H. That is, the functional layer F may serve as a support layer, a protective layer, or a buffer layer. In other embodiments, the functional layer F may include an anti-glare layer, an optical matching layer, or a combination thereof. The aforementioned optical matching layer may, for example, include a plurality of sub-layers with different refractive indexes, which may reduce the possibility of the display screen of the electronic device 10a being affected by ambient light. In some other embodiments, the functional layer F may include a pressure sensing layer or a piezoelectric sensing layer. In further embodiments, the functional layer F may include a heat dissipation layer. In addition, in some embodiments, the functional layer F may have a single-layer structure or a multi-layer structure, but the disclosure is not limited thereto.

In some embodiments, the flexible substrate SB has a surface SB_S2 opposite to the surface SB_S1, and the surface SB_S2 of the flexible substrate SB also has a first region R1 and a second region R2 corresponding to the surface SB_S1. In this embodiment, the surface SB_S2 of the flexible substrate SB has a plurality of grooves Gr. The plurality of grooves Gr, for example, at least partially overlap the color filter pattern CF2 in the top view direction n of the flexible substrate SB. In detail, the plurality of grooves Gr may include, for example, a groove Gr1, a groove Gr2, and a groove Gr3. The groove Gr1, for example, at least partially overlaps the color filter unit CF21, the groove Gr2, for example, at least partially overlaps the color filter unit CF22, and the groove Gr3, for example, at least partially overlaps the color filter unit CF23. In some embodiments, the groove Gr1, the groove Gr2, and the groove Gr3 may have different depths. For example, the depth T1 of the groove Gr1, the depth T2 of the groove Gr2, and the depth T3 of the groove Gr3 may be different from each other. The depth of each of the plurality of grooves Gr may, for example, increase as the distance from the first region R1 increases. In detail, in this embodiment, the groove Gr2 is farther away from the first region R1 than the groove Gr1, and the groove Gr3 is farther away from the first region R1 than the groove Gr2. The depth T1 of the groove Gr1 is smaller than the depth T2 of the groove Gr2, and the depth T2 of the groove Gr2 is smaller than the depth T3 of the groove Gr3, but the disclosure is not limited thereto. Forming the plurality of grooves Gr on the surface SB_S2 of the flexible substrate SB may improve the bendability of the electronic device 10a and/or reduce the bending stress generated when the electronic device 10a is bent, thereby improving the reliability of the electronic device 10a. Furthermore, since the groove Gr at least partially overlaps the color filter pattern CF2, when the electronic device 10a is bent, the color filter pattern CF2 and/or the light shielding structure BM disposed in the second region R2 is suppressed from peeling off from the insulating layer PV3, thereby improving the reliability of the electronic device 10a.

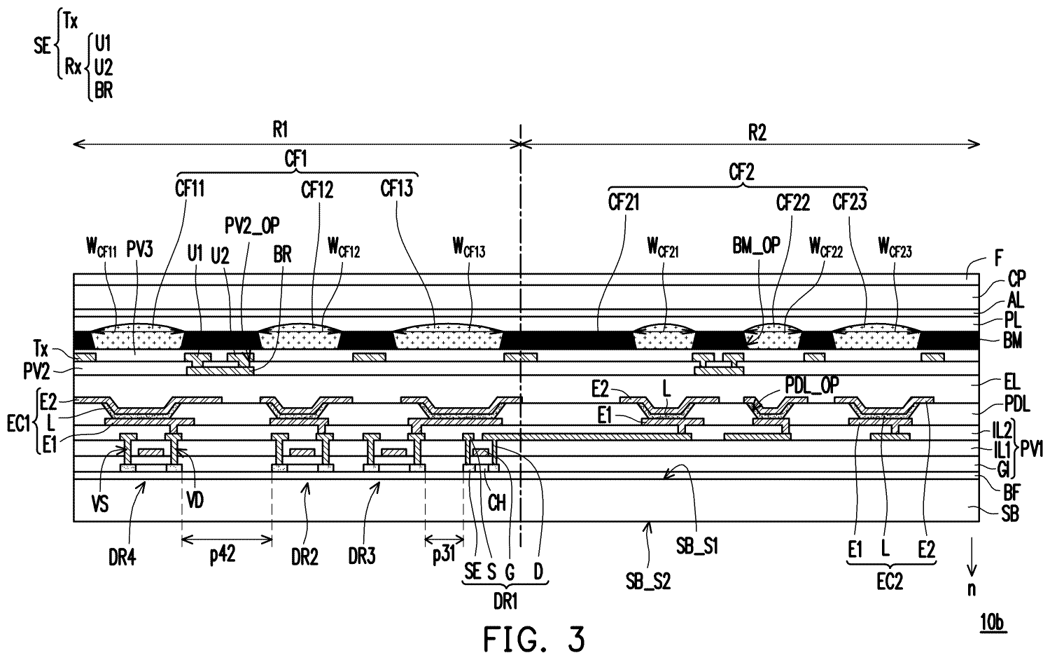

FIG. 3 is a partial cross-sectional view of the electronic device according to the second embodiment of the disclosure. It should be noted that the embodiment of FIG. 3 may use the reference numerals and part of the content of the embodiment of FIG. 2, wherein the same or similar reference numerals are used to represent the same or similar components, and the description of the same technical content is omitted.

Referring to FIG. 3, the main differences between the electronic device 10b of this embodiment and the aforementioned electronic device 10a lie in that: (1) the size of the color filter pattern CF1 disposed on the first region R1 is larger than the size of the color filter pattern CF2 disposed on the second region R2, and (2) the size of the first driving unit DR1 disposed on the curved portion CR of the first region R1 is smaller than the size of the second driving unit DR2 disposed on the flat portion PR of the first region R1. It is worth noting that the “size” mentioned here may be, for example, the length, width and/or area of the driving unit.

In detail, the color filter pattern CF2 located on the second region R2 (having a Gaussian curvature that is not equal to 0) receives relatively large bending stress. Therefore, in this embodiment, the size of the color filter pattern CF2 located on the second region R2 is designed to be relatively small to reduce the influence of the bending stress mentioned above. In some embodiments, the width WCF21 of the color filter unit CF21 may be smaller than the width WCF11 of the color filter unit CF11, the width WCF22 of the color filter unit CF22 may be smaller than the width WCF12 of the color filter unit CF12, and the width WCF23 of the color filter unit CF23 may be smaller than the width WCF13 of the color filter unit CF13. It is worth noting that the “width 5 of the color filter unit” mentioned here may be, for example, the maximum width exposed by the light shielding structure BM.

In this embodiment, based on the design that the color filter pattern CF2 located on the second region R2 has a relatively small size, the size of the electronic component EC2 disposed on the second region R2 may be correspondingly smaller than the size of the electronic component EC1 disposed on the first region R1, but the disclosure is not limited thereto.

In this embodiment, one of the plurality of electronic components EC2 located on the second region R2 is driven by the first driving unit DR1, and one of the plurality of electronic components EC1 located on the first region R1 is driven by the second driving unit DR2. Based on the design that the color filter pattern CF2 (or the electronic component EC2) located on the second region R2 has a relatively small size, the size of the first driving unit DR1 used to drive the electronic component EC2 may be designed to be relatively small. In this embodiment, the size of the first driving unit DR1 is smaller than the size of the second driving unit DR2. It is worth noting that the size of the driving unit mentioned above may be, for example, the ratio of the channel width to the channel length of the thin film transistor, or may be, for example, the area covered by the semiconductor layer, source and drain of the driving unit, but the disclosure is not limited thereto.

In some embodiments, the first driving unit DR1 and/or the second driving unit DR2 may include a U-shaped thin film transistor. The channel length of the U-shaped thin film transistor may be defined as, for example, the distance from the source S to the drain D, and the channel width of the U-shaped thin film transistor may be defined as, for example, the area of the U-shaped channel in the top view direction n of the flexible substrate SB divided by the channel length; or, for example, the path along a U-shaped line connecting all the intermediate points between the source S and the drain D. In other embodiments, the first driving unit DR1 and/or the second driving unit DR2 may include an I-shaped thin film transistor. The channel length of the I-shaped thin film transistor may also be defined as, for example, the distance from the source S to the drain D, and the channel width of the I-shaped thin film transistor may also be defined as, for example, the area of the I-shaped channel in the top view direction n of the flexible substrate SB divided by the channel length; or, for example, the path along a straight line connecting all the intermediate points between the source S and the drain D.

Accordingly, the definition that the size of the first driving unit DR1 is smaller than the size of the second driving unit DR2 may be, for example, that the ratio of the channel width to the channel length of the first driving unit DR1 is smaller than the ratio of the channel width to the channel length of the second driving unit DR2. Specifically, when both the first driving unit DR1 and the second driving unit DR2 are U-shaped thin film transistors, the channel length and the channel width of the first driving unit DR1 and the second driving unit DR2 satisfy the following relationship: U_W1/U_L1<U_W2/U_L2, where U_L1 is the channel length of the first driving unit DR1, U_W1 is the channel width of the first driving unit DR1, U_L2 is the channel length of the second driving unit DR2, and U_W2 is the channel width of the second driving unit DR2. In addition, in this embodiment, when both the first driving unit DR1 and the second driving unit DR2 are I-shaped thin film transistors, the channel length and the channel width of the first driving unit DR1 and the second driving unit DR2 satisfy the following relationship: I_W1/I_L1<I_W2/I_L2, where I_L1 is the channel length of the first driving unit DR1, I_W1 is the channel width of the first driving unit DR1, I_L2 is the channel length of the second driving unit DR2, and I_W2 is the channel width of the second driving unit DR2. That is, the first driving unit DR1 may have an equivalent resistance that is greater than the equivalent resistance of the second driving unit DR2, for example.

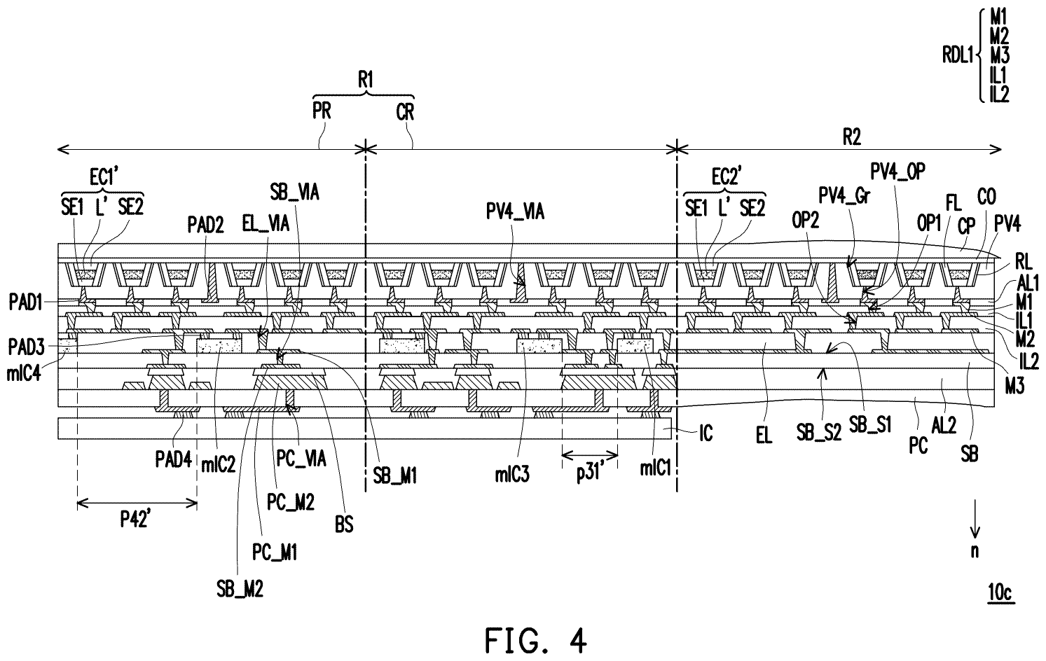

FIG. 4 is a partial cross-sectional view of the electronic device according to the third embodiment of the disclosure. It should be noted that the embodiment of FIG. 4 may use the reference numerals and part of the content of the embodiment of FIG. 2, wherein the same or similar reference numerals are used to represent the same or similar components, and the description of the same technical content is omitted.

Referring to FIG. 4, the main differences between the electronic device 10c of this embodiment and the aforementioned electronic device 10a lie in that: (1) the electronic component EC′ includes an inorganic light-emitting diode, and (2) the driving unit DR′ includes an integrated circuit unit mIC.

In this embodiment, the electronic component EC′ may include, for example, a vertical micro-light-emitting diode. In detail, the electronic component EC′ may include a first semiconductor layer SE1, a second semiconductor layer SE2, and a light-emitting layer L′.

For example, the first semiconductor layer SE1 and the second semiconductor layer SE2 may each include an N-type doped semiconductor and a P-type doped semiconductor; or may each include a P-type doped semiconductor and an N-type doped semiconductor. The materials of the first semiconductor layer SE1 and the second semiconductor layer SE2 may include, for example, gallium nitride (GaN), indium gallium nitride (InGaN), gallium arsenide (GaAs), aluminum gallium indium phosphide (AlGaInP), other materials composed of Group IIIA and Group VA elements, or other suitable materials, but the disclosure is not limited thereto. The light-emitting layer L′ may, for example, have a quantum well (QW), which may be, for example, a single quantum well (SQW), a multiple quantum well (MQW), or other quantum wells. Accordingly, the holes and electrons provided by the first semiconductor layer SE1 and the second semiconductor layer SE2 may be combined in the light-emitting layer L′ and emit light energy.

In this embodiment, the electronic device 10c further includes an insulating layer PV4, a separation layer RL, a filling layer FL, a connection pad PAD1, a connection pad PAD2, and a common electrode CO.

The insulating layer PV4 includes, for example, a plurality of grooves PV4_Gr, a plurality of openings PV4_OP, and a plurality of vias PV4_VIA. The groove PV4_Gr is connected to the corresponding opening PV4_OP, and the plurality of vias PV4_VIA, for example, penetrate the insulating layer PV4. In this embodiment, one of the plurality of electronic components EC′ may be disposed in the corresponding groove PV4_Gr, and the opening PV4_OP may expose a portion of the electronic component EC′. The material of the insulating layer PV4 may be, for example, an organic material (such as polytetrafluoroethylene, polyimide, parylene, benzocyclobutene, or other suitable materials), but the disclosure is not limited thereto.

The separation layer RL is, for example, disposed in the opening PV4_OP of the insulating layer PV4, and is, for example, disposed adjacent to or surrounding the electronic component EC′. In some embodiments, the material of the separation layer RL includes, for example, a light-absorbing material, a reflective material, a scattering material, or a combination thereof, but the disclosure is not limited thereto. The separation layer RL may, for example, reduce the possibility of light emitted by adjacent electronic components EC′ interfering with each other and/or may, for example, reduce the problem of light leakage from the electronic component EC′. In some embodiments, the separation layer RL may include a distributed Bragg reflector (DBR), but the disclosure is not limited thereto.

The filling layer FL is, for example, disposed in the opening PV4_OP of the insulating layer PV4, and is, for example, disposed adjacent to or surrounding the electronic component EC′. In some embodiments, the filling layer FL is disposed between the separation layer RL and the electronic component EC′, but the disclosure is not limited thereto. The filling layer FL may serve, for example, to secure or protect the electronic component EC′. In some embodiments, the filling layer FL may include a transparent material. For example, the material of the filling layer FL may include epoxy resin, acrylic, other suitable materials, or a combination of the aforementioned, but the disclosure is not limited thereto.

The connection pad PAD1 is, for example, disposed on a surface of the insulating layer PV4 facing the flexible substrate SB, and may, for example, at least partially overlap the opening PV4_OP of the insulating layer PV4. A portion of the connection pad PAD1 may be disposed in the opening PV4_OP. In this embodiment, the first semiconductor layer SE1 of the electronic component EC′ may be electrically connected to the connection pad PAD1 through the corresponding opening PV4_OP. The connection pad PAD2 is, for example, disposed on the surface of the insulating layer PV4 facing the flexible substrate SB, and may be electrically connected to the common electrode CO which will be introduced later, for example.

The common electrode CO is, for example, disposed on a surface of the insulating layer PV4 away from the flexible substrate SB, and may, for example, at least partially overlap the groove PV4_Gr of the insulating layer PV4. In this embodiment, the common electrode CO is electrically connected to the second semiconductor layer SE2 of the electronic component EC′, and may be electrically connected to the connection pad PAD2 through the corresponding via PV4_VIA.

The driving unit DR′ includes, for example, an integrated circuit unit mIC. For example, the integrated circuit unit mIC may include suitable semiconductor chips such as an application-specific integrated circuit chip, an analog chip, a digital chip, a voltage regulator chip, a sensor chip and/or a memory chip, but the disclosure is not limited thereto. In some embodiments, a chip adhesive film (not shown) may be formed between the integrated circuit unit mIC and the surface SB_S1 of the flexible substrate SB for the integrated circuit unit mIC to be attached to the surface SB_SI of the flexible substrate SB. The material of the chip adhesive film may include, for example, an organic material, an inorganic material, or other suitable adhesive materials, but the disclosure is not limited thereto. In this embodiment, the integrated circuit unit mIC is configured to face up. That is to say, in some embodiments, a connection pad PAD3 is disposed on a side of the integrated circuit unit mIC away from the surface SB_S1 of the flexible substrate SB, but the disclosure is not limited thereto. The connection pad PAD3 overlaps the flexible substrate SB, for example. In some embodiments, the integrated circuit unit mIC is bonded to the connection pad PAD3 to be electrically connected to a redistribution structure RDL1 and/or a redistribution structure RDL2 which will be introduced later.

In this embodiment, the integrated circuit unit mIC is disposed on the surface SB_S1 of the flexible substrate SB. That is, the integrated circuit unit mIC is disposed above the flexible substrate SB, but the disclosure is not limited thereto. In other embodiments, the integrated circuit unit mIC may be disposed on the surface SB_S2 of the flexible substrate SB. That is, the integrated circuit unit mIC may be disposed under the flexible substrate SB.

In this embodiment, the integrated circuit unit mIC includes a first integrated circuit unit mIC1, a second integrated circuit unit mIC2, a third integrated circuit unit mIC3, and a fourth integrated circuit unit mIC4.

The first integrated circuit unit mIC1 is, for example, disposed on a non-corner region of the flexible substrate SB. In this embodiment, the first integrated circuit unit mIC1 may be disposed on the flat portion PR and/or the curved portion CR of the first region R1 and may be bonded to the connection pad PAD3. In detail, in some embodiments, the first integrated circuit unit mIC1 may be disposed merely on the flat portion PR of the first region R1. In other embodiments, the first integrated circuit unit mIC1 may be disposed merely on the curved portion CR of the first region R1. In this embodiment, the first integrated circuit unit mIC1 is disposed on the flat portion PR and the curved portion CR of the first region R1.

The second integrated circuit unit mIC2 is, for example, disposed on the non-corner region of the flexible substrate SB. In some embodiments, the second integrated circuit unit mIC2 is disposed on the flat portion PR of the first region R1. In this embodiment, the first integrated circuit unit mIC1 is closer to the curved portion CR than the second integrated circuit unit mIC2. In detail, the second integrated circuit unit mIC2 is, for example, disposed approximately on the middle region of the flat portion PR, and the first integrated circuit unit mIC1 is, for example, disposed approximately on the edge region of the flat portion PR, but the disclosure is not limited thereto. The second integrated circuit unit mIC2 may, for example, have the same or similar structure as the first integrated circuit unit mIC1, but the disclosure is not limited thereto.

The third integrated circuit unit mIC3 and the fourth integrated circuit unit mIC4 are, for example, disposed on the first region R1 of the flexible substrate SB. In some embodiments, the third integrated circuit unit mIC3 is adjacent to the first integrated circuit unit mIC1. That is, the third integrated circuit unit mIC3 may, for example, be disposed on the flat portion PR and/or the curved portion CR of the first region R1. In some embodiments, the fourth integrated circuit unit mIC4 is adjacent to the second integrated circuit unit mIC2. That is, the fourth integrated circuit unit mIC4 may be disposed on the flat portion PR of the first region R1, for example. The third integrated circuit unit mIC3 and the fourth integrated circuit unit mIC4 may, for example, have the same or similar structure as the first integrated circuit unit mIC1, but the disclosure is not limited thereto.

In this embodiment, the integrated circuit unit mIC (including the first integrated circuit unit mIC1, the second integrated circuit unit mIC2, the third integrated circuit unit mIC3, and the fourth integrated circuit unit mIC4) is not disposed on the second region R2 (having a Gaussian curvature that is not equal to 0) of the flexible substrate SB. That is, the integrated circuit unit mIC is disposed on the first region R1 (having a Gaussian curvature that is equal to 0) of the flexible substrate SB. Accordingly, when the electronic device 10c is bent, electrical abnormalities of the integrated circuit unit mIC resulting from bending and/or falling of the integrated circuit unit mIC from the flexible substrate SB may be reduced, thereby improving the reliability of the electronic device 10c.

In this embodiment, since the integrated circuit unit mIC (including the first integrated circuit unit mIC1, the second integrated circuit unit mIC2, the third integrated circuit unit mIC3, and the fourth integrated circuit unit mIC4) is not disposed on the second region R2 (having a Gaussian curvature that is not equal to 0) of the flexible substrate SB, a relatively large number of integrated circuit units are disposed on a region in the first region R1 close to the second region R2, so as to drive the electronic components EC2′ located on the second region R2 through these integrated circuit units. For example, one of the plurality of electronic components EC2′ located on the second region R2 of the flexible substrate SB may be driven by the first integrated circuit unit mIC1 located on the first region R1 of the flexible substrate SB. Accordingly, in this embodiment, the pitch p42′ between the fourth integrated circuit unit mIC4 and the second integrated circuit unit mIC2 located on the first region R1 is greater than the pitch p31′ between the third integrated circuit unit mIC3 and the first integrated circuit unit mIC1 located on the first region R1. It is worth noting that the “pitch” mentioned here may be, for example, the shortest distance between adjacent integrated circuit units, and the shortest distance is measured from the respective edges of the adjacent integrated circuit units, but the disclosure is not limited thereto. From another perspective, the density of the integrated circuit units (the first integrated circuit unit mIC1 and the third integrated circuit unit mIC3) disposed on the corner region of the first region R1 is greater than the density of the integrated circuit units (the second integrated circuit unit mIC2 and the fourth integrated circuit unit mIC4) disposed on the middle region of the first region R1. That is, the number of the first integrated circuit unit mIC1 and the third integrated circuit unit mIC3 in the same cross-sectional area of the first region R1 is greater than the number of the second integrated circuit unit mIC2 and the fourth integrated circuit unit mIC4 in the same cross-sectional area of the first region R1.

In this embodiment, the electronic device 10c further includes an encapsulation layer EL and a supporting substrate PC.

The encapsulation layer EL, for example, surrounds the integrated circuit unit mIC and exposes a portion of the connection pad PAD3. The material of the encapsulation layer EL may be, for example, an organic material or other suitable materials. In this embodiment, the material of the encapsulation layer EL may be epoxy resin, but the disclosure is not limited thereto.

The supporting substrate PC is, for example, disposed under the flexible substrate SB. In this embodiment, the supporting substrate PC is, for example, disposed on the surface SB_S2 of the flexible substrate SB. The supporting substrate PC may be, for example, the flexible circuit board FPC in the above embodiment, but the disclosure is not limited thereto. In this embodiment, a chip IC may be disposed on a surface of the supporting substrate PC away from the flexible substrate SB. In this embodiment, the chip IC may be disposed on the supporting substrate PC through the connection pad PAD4. The chip IC may, for example, include a chip that integrates a touch function and a driving function (Touch with Display Driver; TTDI), but the disclosure is not limited thereto. In detail, the chip IC may be electrically connected to the integrated circuit unit mIC through the following interconnection to control the integrated circuit unit mIC, which allows the integrated circuit unit mIC to send corresponding signals to the electronic component EC′ and/or to determine the touch position and send corresponding signals according to touch signals from the outside, but the disclosure is not limited thereto. In this embodiment, the chip IC may sequentially pass through the conductive layer PC_M1 disposed on the surface of the supporting substrate PC away from the flexible substrate SB, the conductive via PC_VIA penetrating the supporting substrate PC, the conductive layer PC_M2 disposed on the surface of the supporting substrate PC facing the flexible substrate SB, the bonding structure BS bonded to the conductive layer PC_M2 and the conductive layer SB_M2, the conductive layer SB_M2 disposed on the surface SB_S2 of the flexible substrate SB, the conductive via SB_VIA penetrating the flexible substrate SB, the conductive layer SB_M1 disposed on the surface SB_S1 of the flexible substrate SB, and the conductive via EL_VIA penetrating the encapsulation layer EL to be electrically connected to the integrated circuit unit mIC.

In this embodiment, the chip IC is not disposed on the second region R2 (having a Gaussian curvature that is not equal to 0) of the flexible substrate SB. That is, the chip IC is disposed on the first region R1 (having a Gaussian curvature that is equal to 0) of the flexible substrate SB. Accordingly, when the electronic device 10c is bent, electrical abnormalities of the chip IC resulting from bending may be reduced, thereby improving the reliability of the electronic device 10c.

In this embodiment, the electronic device 10c further includes a redistribution structure RD1, an adhesive layer AL1, and an adhesive layer AL2.

The redistribution structure RDL1 is, for example, disposed between the encapsulation layer EL and the electronic component EC′, and the adhesive layer AL1 is, for example, disposed between the redistribution structure RDL1 and the electronic component EC′. The redistribution structure RDL1 may be bonded to the insulating layer PV4 through the adhesive layer AL1, for example. In some embodiments, the redistribution structure RDL1 sequentially includes a conductive layer M1, an insulating layer IL1 having a plurality of openings OP1, a conductive layer M2, an insulating layer IL2 having a plurality of openings OP2, and a conductive layer M3. The conductive layer M1 may be electrically connected to the conductive layer M2 through the opening OP1, and the conductive layer M2 may be electrically connected to the conductive layer M3 through the opening OP2. The adhesive layer AL1 may, for example, include a conductive material. For example, the adhesive layer AL1 may include an anisotropic conductive film (ACF) or other suitable materials, but the disclosure is not limited thereto.

The adhesive layer AL2 is, for example, disposed between the flexible substrate SB and the supporting substrate PC, and the supporting substrate PC may be bonded to the flexible substrate SB through the adhesive layer AL2, for example. In some embodiments, the adhesive layer AL2 may include an anisotropic conductive film (ACF) or other suitable materials, but the disclosure is not limited thereto.

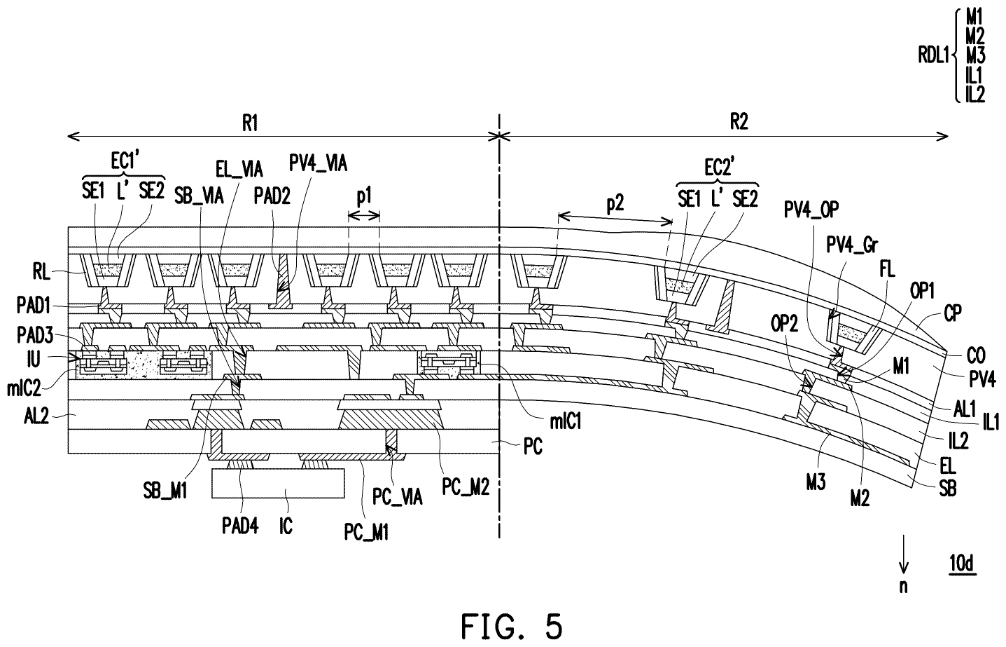

FIG. 5 is a partial cross-sectional view of the electronic device according to the fourth embodiment of the disclosure. It should be noted that the embodiment of FIG. 5 may use the reference numerals and part of the content of the embodiment of FIG. 4, wherein the same or similar reference numerals are used to represent the same or similar components, and the description of the same technical content is omitted.

Referring to FIG. 5, the main differences between the electronic device 10d of this embodiment and the aforementioned electronic device 10c lie in that: (1) the pitch between adjacent electronic components EC2′ disposed on the second region R2 is greater than the pitch between adjacent electronic components EC1′ disposed on the first region R1, and (2) the size of the integrated circuit unit disposed on the curved portion CR of the first region R1 is smaller than the size of the integrated circuit unit disposed on the flat portion PR of the first region R1.

In this embodiment, considering that the resolution in the second region R2 may be less than the resolution in the first region R1, the pitch p2 between adjacent electronic components EC2′ located on the second region R2 may be greater than the pitch p1 between adjacent electronic components EC1′ disposed on the first region R1. It is worth noting that the “pitch” mentioned here may be, for example, the shortest distance between adjacent electronic components, and the shortest distance is measured from the respective edges of the adjacent electronic components, but the disclosure is not limited thereto.

Similarly, in this embodiment, considering that the contrast in the second region R2 may be less than the contrast in the first region R1, the size of the integrated circuit unit disposed on the curved portion CR of the first region R1 is smaller than the size of the integrated circuit unit disposed on the flat portion PR of the first region R1.

In detail, taking the first integrated circuit unit mIC1 and the second integrated circuit unit mIC2 as an example, the size of the first integrated circuit unit mIC1 is smaller than the size of the second integrated circuit unit mIC2. It is worth noting that the size of the integrated circuit unit mentioned above may be, for example, the number of microchip units IU included.

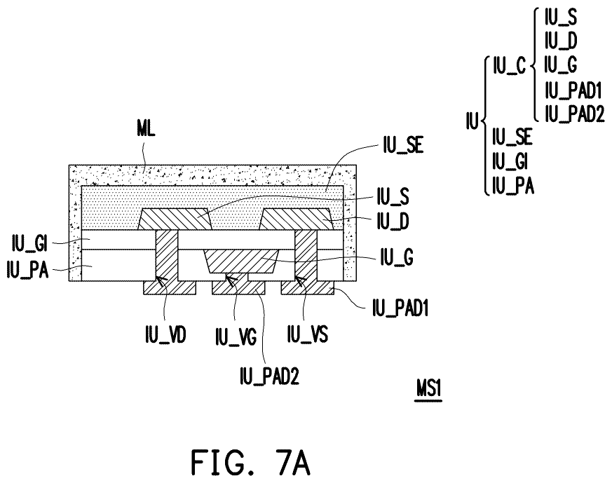

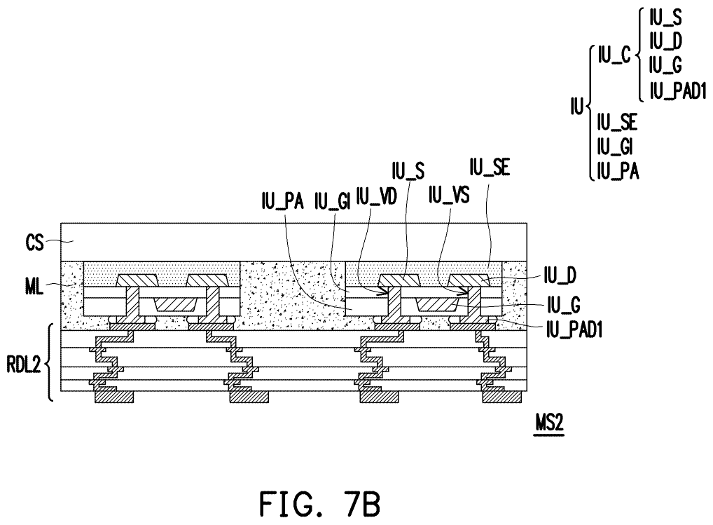

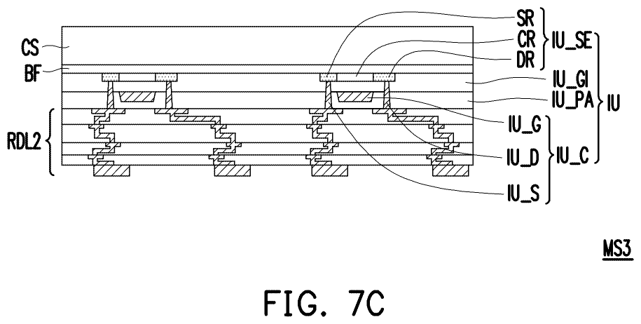

For example, as shown in FIG. 5, the first integrated circuit unit mIC1 may include a packaging structure packaging one microchip unit IU, and the second integrated circuit unit mIC2 may include a packaging structure packaging two microchip units IU, but the disclosure is not limited thereto. The detailed structure of the microchip unit IU will be introduced in FIG. 7A to FIG. 7C and will not be repeated here.

In this embodiment, the first integrated circuit unit mIC1 is configured to face down, but the disclosure is not limited thereto.

Further, in this embodiment, a portion of the bottom surface SB_S2 of the flexible substrate is exposed by the supporting substrate PC. It is worth noting that the “exposed” mentioned here may, for example, mean that the bottom surface of the flexible substrate is not covered or overlapped by the supporting substrate PC. That is to say, the supporting substrate PC is not disposed on the second region R2 (having a Gaussian curvature that is not equal to 0) of the flexible substrate SB. In other words, the supporting substrate PC is disposed on the first region R1 (having a Gaussian curvature that is equal to 0) of the flexible substrate SB. Accordingly, when the electronic device 10d is bent, electrical abnormalities of the supporting substrate PC resulting from bending may be reduced, thereby improving the reliability of the electronic device 10d. Furthermore, the bendability of the electronic device 10d may be improved.

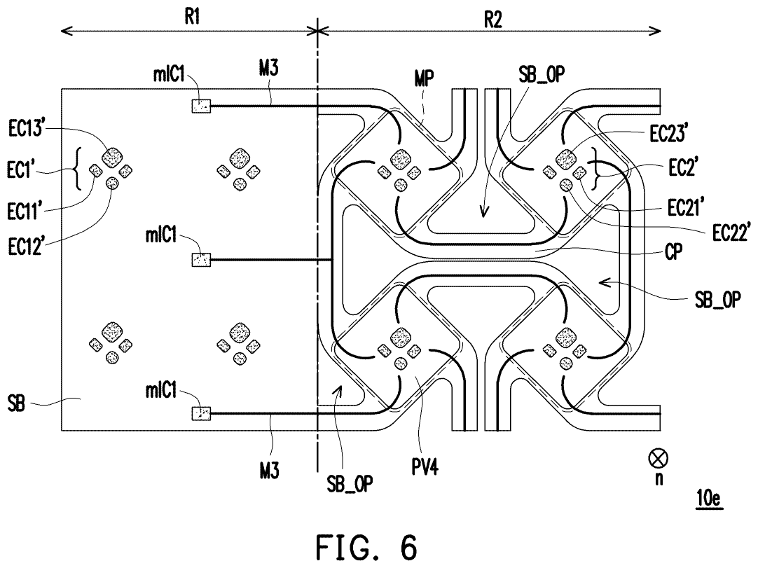

FIG. 6 is a partial top view of the electronic device according to another embodiment of the disclosure. It should be noted that the embodiment of FIG. 6 may use the reference numerals and part of the content of the embodiment of FIG. 5, wherein the same or similar reference numerals are used to represent the same or similar components, and the description of the same technical content is omitted.

Referring to FIG. 6, the main differences between the electronic device 10e of this embodiment and the aforementioned electronic device 10d lie in that the flexible substrate SB has a plurality of openings SB_OP in the second region R2.

In this embodiment, the surface SB_S2 of the flexible substrate SB has a plurality of openings SB_OP, and the plurality of openings SB_OP present an irregular shape in the partial top view shown in FIG. 6, but the disclosure is not limited thereto. For example, the plurality of openings SB_OP do not overlap at least the conductive layer (including the conductive layer that electrically connects the first integrated circuit unit mIC1 and the electronic component EC2′, such as the conductive layer M3 shown in FIG. 6) and the electronic component EC2′ inside the electronic device 10e in the top view direction n of the flexible substrate SB. Forming the plurality of openings SB_OP on the surface SB_S2 of the flexible substrate SB may improve the bendability of the electronic device 10e and/or reduce the bending stress generated when the electronic device 10e is bent without affecting the yield of the electronic device 10e, thereby improving the reliability of the electronic device 10e. In some embodiments, the electronic components EC1′ may include an electronic component EC11′, an electronic component EC12′, and an electronic component EC13′ that emit light of different colors; and the electronic components EC2′ may include an electronic component EC21′, an electronic component EC22′, and an electronic component EC23′ that emit light of different colors, but the disclosure is not limited thereto.

Based on the design of the plurality of openings SB_OP, the flexible substrate SB in the electronic device 10e of this embodiment includes a plurality of main parts MP and a plurality of connection parts CP. The main part MP may, for example, be configured to provide a region for disposing a light-emitting unit or other active elements; and the connection part CP may, for example, be configured to change the distance between the adjacent main parts MP connected. For example, when the electronic device 10e is deformed (for example, stretched), the connection part CP may be deformed, which causes the size (such as length) of the connection part CP to change, thereby changing the distance between the main parts MP. Alternatively, by designing different patterns, the connection parts CP may have different sizes, thereby changing the distance between adjacent main parts MP. In some embodiments, at least one of the plurality of connection parts CP connects two adjacent main parts of the plurality of main parts MP. For example, as shown in the partial top view of FIG. 6, four main parts MP are provided, and the adjacent main parts MP are connected by the connection part CP. In addition, in some embodiments, one of the plurality of electronic components EC2′ located on the second region R2 is disposed on one of the two adjacent main parts MP.

FIG. 7A is a partial cross-sectional view of the chip packaging structure of the microchip unit according to an embodiment of the disclosure.

Referring to FIG. 7A, the chip packaging structure MS1 of this embodiment includes a microchip unit IU, in which one microchip unit IU is packaged through a packaging structure ML. In some embodiments, the microchip unit IU includes a semiconductor layer IU_SE and a conductive structure IU_C, and the conductive structure IU_C overlaps the semiconductor layer IU_SE. The material of the semiconductor layer IU_SE includes, for example, single crystal silicon or polycrystalline silicon, which may include, for example, silicon carbide (SiC), silicon (Si), germanium (Ge), gallium arsenide (GaAs), indium phosphide (InP), gallium nitride (GaN), or other suitable semiconductor materials, but the disclosure is not limited thereto. In some embodiments, the conductive structure IU_C includes a gate IU_G, a source IU_S, a drain IU_D, a connection pad IU_PAD1, and a connection pad IU_PAD2, but the disclosure is not limited thereto. In some embodiments, the microchip unit IU may further include an insulating layer IU_GI and an insulating layer IU_PA, but the disclosure is not limited thereto.

The chip packaging structure MS1 is, for example, configured to face down, in which the semiconductor layer IU_SE, the insulating layer IU_GI, and the insulating layer IU_PA are stacked in this order. Specifically, the drain IU_D and the source IU_S are conductors formed by the semiconductor layer IU_SE through a doping process, and are respectively electrically connected to the connection pad IU_PAD1 through the via IU_VS and the via IU_VD that penetrate the insulating layer IU_GI and the insulating layer IU_PA. The gate IU_G is disposed on the insulating layer IU_GI and covered by the insulating layer IU_PA, and is electrically connected to the connection pad IU_PAD2 through the via IU_VG. The packaging structure ML surrounds the semiconductor layer IU_SE and the conductive structure IU_C. In this embodiment, the packaging structure ML is located on three sides of the semiconductor layer IU_SE, the insulating layer IU_GI, and the insulating layer IU_PA, and at least exposes the connection pad IU_PAD1 and the connection pad IU_PAD2, but the disclosure is not limited thereto.

FIG. 7B is a partial cross-sectional view of the chip packaging structure of the microchip unit according to another embodiment of the disclosure. It should be noted that the embodiment of FIG. 7B may use the reference numerals and part of the content of the embodiment of FIG. 7A, wherein the same or similar reference numerals are used to represent the same or similar components, and the description of the same technical content is omitted.

Referring to FIG. 7B, the chip packaging structure MS2 of this embodiment is, for example, a panel level package (PLP). In detail, the chip packaging structure MS2 includes a plurality of microchip units IU attached to a panel-level glass substrate CS, which is formed using a chip first process. Panel-level packaging uses the panel-level glass substrate CS, which increases the production capacity compared with the existing wafer-level packaging. In this embodiment, the packaging structure MS2 includes a redistribution structure RDL2. The redistribution structure RDL2 includes a plurality of conductive layers and a plurality of insulating layers to serve as the wiring layer of the electronic device and provide the required conductive transmission path. The redistribution structure RDL2 may be the redistribution structure RDL1 of the above embodiment or other suitable redistribution structures, but the disclosure is not limited thereto.

FIG. 7C is a partial cross-sectional view of the chip packaging structure of the microchip unit according to yet another embodiment of the disclosure. It should be noted that the embodiment of FIG. 7C may use the reference numerals and part of the content of the embodiment of FIG. 7B, wherein the same or similar reference numerals are used to represent the same or similar components, and the description of the same technical content is omitted.

Referring to FIG. 7C, the chip packaging structure MS3 of this embodiment is, for example, a glass chip (glass IC). In detail, the manufacturing process of the chip packaging structure MS3 includes sequentially forming the components of the microchip unit IU and/or the components of the redistribution structure RDL2 on the glass substrate CS. In this embodiment, the microchip unit IU in the chip packaging structure MS3 includes a top gate thin film transistor, but the disclosure is not limited thereto. In addition, a buffer layer BF may be disposed between the insulating layer IU_GI and the glass substrate CS, for example, but the disclosure is not limited thereto. In this embodiment, the semiconductor layer IU_SE may include a source region SR, a drain region DR, and a channel region CR located between the source region SR and the drain region DR. The source region SR is electrically connected to the source IU_S, the drain region DR is electrically connected to the drain IU_D, and the channel region CR overlaps the gate IU_G.

In other embodiments, the method of packaging the microchip unit IU may also include using System on a Chip (SoC), System in a Package (SiP), flip chip, or other suitable packaging processes, but the disclosure is not limited thereto.

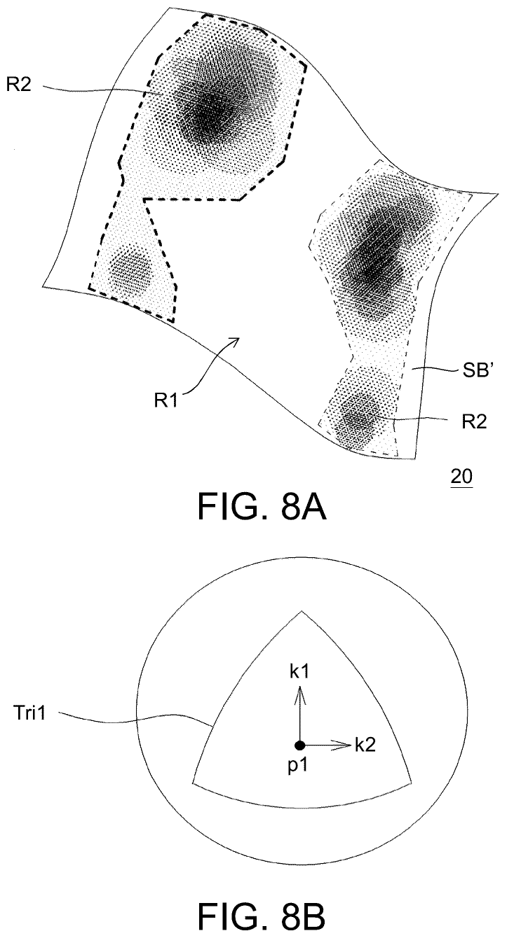

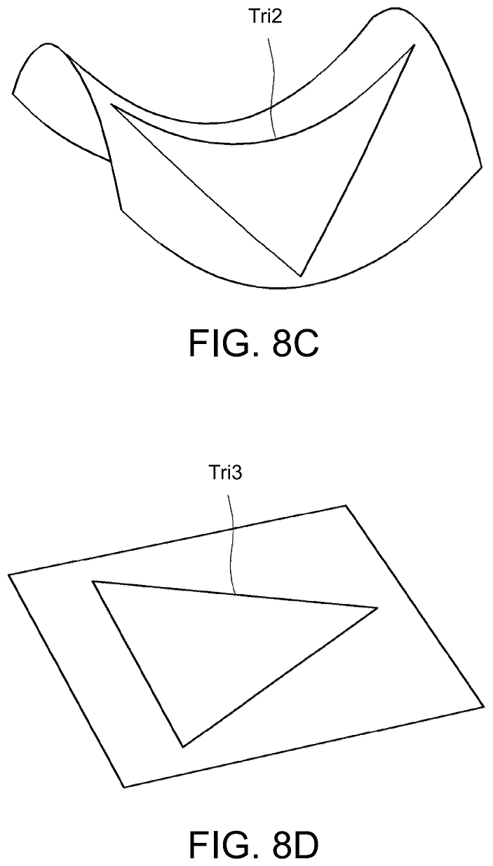

FIG. 8A to FIG. 8D are schematic views of regions having different Gaussian curvatures on the curved surface of the flexible substrate included in the electronic device according to an embodiment of the disclosure.

Referring to FIG. 8A, the flexible substrate SB′ included in an electronic device 20 has a curved surface. The curved surface includes a first region R1 and at least one second region R2. The Gaussian curvature of the first region R1 is equal to 0, and the Gaussian curvature of the second region R2 is not equal to 0 and may be greater than 0 or less than 0. The method of determining the Gaussian curvature in this embodiment has been described in the above embodiment, and will not be repeated here.

Referring to FIG. 8B to FIG. 8D, FIG. 8B is a schematic view showing that the Gaussian curvature of the surface of the flexible substrate SB′ is positive; FIG. 8C is a schematic view showing that the Gaussian curvature of the surface of the flexible substrate SB′ is negative; and FIG. 8D is a schematic view showing that the Gaussian curvature of the surface of the flexible substrate SB′ is 0.

As shown in FIG. 8B, the curved surface having a positive Gaussian curvature may be similar to a spherical shape or a convex shape; and as shown in FIG. 8C, the curved surface having a negative Gaussian curvature may be similar to a saddle shape, but the disclosure is not limited thereto. The first method mentioned in the above embodiment of the disclosure may be as follows. First, any three non-collinear points on a curved surface are connected to form a triangle, and then it is determined whether the sum of the interior angles of the triangle is greater than 180 degrees, equal to 180 degrees, or less than 180 degrees. As shown in FIG. 8B, when the Gaussian curvature of the curved surface is positive, any three points on the curved surface are connected to form a triangle Tri1, and the sum of the interior angles of the triangle Tri1 is greater than 180 degrees. As shown in FIG. 8C, when the Gaussian curvature of the curved surface is negative, any three points on the curved surface are connected to form a triangle Tri2, and the sum of the interior angles of the triangle Tri2 is less than 180 degrees. As shown in FIG. 8D, when the Gaussian curvature of the curved surface is 0, any three points on the curved surface are connected to form a triangle Tri3, and the sum of the interior angles of the triangle Tri3 is equal to 180 degrees. It is worth noting that if the sum of the interior angles of the triangle Tri3 is within an error range of 180 degrees plus or minus 5 degrees, the Gaussian curvature may be considered as 0.

The second method of determining Gaussian curvature mentioned in the above embodiment of the disclosure may be as follows. First, a point P1 on a curved surface is picked randomly, wherein there are two mutually perpendicular direction vectors at this point P1, and the two direction vectors respectively have a curvature k1 and a curvature k2. The Gaussian curvature of the curved surface is the product of the curvature k1 of the direction vector and the curvature k2 of the direction vector. Taking FIG. 8B as an example, the curvature k1 of the direction vector and the curvature k2 of the direction vector are both positive, so the product of the curvatures of the two direction vectors is also positive. The method of determining the Gaussian curvatures of the curved surfaces in FIG. 8C and FIG. 8D is the same as above and thus will not be repeated.

To sum up, in the electronic device provided by some embodiments of the disclosure, the screen-to-body ratio and/or display effects of the electronic device are improved by disposing color filter patterns and/or micro-light-emitting diodes on the curved portion of the first region and/or the second region (having a Gaussian curvature that is not equal to 0) of the flexible substrate.

In the electronic device provided by other embodiments of the disclosure, the driving unit (including a transistor and/or an integrated circuit unit) is not disposed on the second region (having a Gaussian curvature that is not equal to 0) of the flexible substrate. That is, the driving unit is disposed on the first region (having a Gaussian curvature that is equal to 0) of the flexible substrate. Accordingly, when the electronic device is bent, electrical abnormalities of the driving unit resulting from the bending and/or falling of the driving unit from the flexible substrate may be reduced, thereby improving the reliability of the electronic device.

What is claimed is:

1. An electronic device, comprising:
a flexible substrate comprising a surface which has a first region and a second region, wherein the first region has a Gaussian curvature that is equal to 0, and the second region has a Gaussian curvature that is not eqaul to 0;
a plurality of electronic components disposed on the flexible substrate; and
a first driving unit disposed on the first region of the flexible substrate,
wherein one of the plurality of electronic components located on the second region of the flexible substrate is driven by the first driving unit.

2. The electronic device according to claim 1, wherein the first region comprises a flat portion and a curved portion, the curved portion connects the flat portion and the second region, and the first driving unit is disposed on the flat portion.

3. The electronic device according to claim 1, wherein the first region comprises a flat portion and a curved portion, the curved portion connects the flat portion and the second region, and the first driving unit is disposed on the curved portion.

4. The electronic device according to claim 1, further comprising a second driving unit disposed on the first region of the flexible substrate, wherein the first region comprises a flat portion and a curved portion, the curved portion connects the flat portion and the second region, the first driving unit and the second driving unit are disposed on the flat portion, and the first driving unit is closer to the curved portion than the second driving unit.

5. The electronic device according to claim 4, further comprising a third driving unit and a fourth driving unit, wherein the third driving unit and the fourth driving unit are disposed on the first region of the flexible substrate, the third driving unit is adjacent to the first driving unit, the fourth driving unit is adjacent to the second driving unit, and a pitch between the fourth driving unit and the second driving unit is greater than a pitch between the third driving unit and the first driving unit.

6. The electronic device according to claim 1, wherein a pitch between two adjacent electronic components of the plurality of electronic components located on the first region is smaller than a pitch between two adjacent electronic components of the plurality of electronic components located on the second region.

7. The electronic device according to claim 1, wherein the flexible substrate comprises a plurality of main parts and a plurality of connection parts, at least one of the plurality of connection parts connects two adjacent main parts of the plurality of main parts, and one of the plurality of electronic components is disposed on one of the two adjacent main parts.

8. The electronic device according to claim 1, further comprising a supporting substrate, wherein the supporting substrate is disposed under the flexible substrate, and a portion of a bottom surface of the flexible substrate is exposed by the supporting substrate.

9. The electronic device according to claim 1, wherein the second region is a corner region of the electronic device.

10. An electronic device, comprising:
a flexible substrate comprising a corner region and a non-corner region, wherein the corner region has an arc-shaped edge in a top view of the electronic device;
a first connection pad overlapping the flexible substrate;
a plurality of electronic components disposed on the flexible substrate; and
a first integrated circuit unit bonded to the first connection pad and disposed on the non-corner region of the flexible substrate,
wherein one of the plurality of electronic components located on the corner region of the flexible substrate is driven by the first integrated circuit unit.

11. The electronic device according to claim 10, wherein the non-corner region comprises a flat portion and a curved portion, the curved portion connects the flat portion and the corner region, and the first integrated circuit unit is disposed on the curved portion.

12. The electronic device according to claim 10, wherein the first integrated circuit unit is disposed under the flexible substrate.

13. The electronic device according to claim 10, further comprising a second integrated circuit unit disposed on the non-corner region of the flexible substrate, wherein the non-corner region comprises a flat portion and a curved portion, the curved portion connects the flat portion and the corner region, the first integrated circuit unit and the second integrated circuit unit are disposed on the flat portion, and the first integrated circuit unit is closer to the curved portion than the second integrated circuit unit.

14. The electronic device according to claim 13, further comprising a third integrated circuit unit and a fourth integrated circuit unit, wherein the third integrated circuit unit and the fourth integrated circuit unit are disposed on the non-corner region of the flexible substrate, the third integrated circuit unit is adjacent to the first integrated circuit unit, the fourth integrated circuit unit is adjacent to the second integrated circuit unit, and a pitch between the fourth integrated circuit unit and the second integrated circuit unit is greater than a pitch between the third integrated circuit unit and the first integrated circuit unit.

15. The electronic device according to claim 10, wherein a pitch between two adjacent electronic components of the plurality of electronic components located on the corner region is smaller than a pitch between two adjacent electronic components of the plurality of electronic components located on the non-corner region.

16. The electronic device according to claim 10, further comprising a second integrated circuit unit disposed on the non-corner region of the flexible substrate, wherein the non-corner region comprises a flat portion and a curved portion, the curved portion connects the flat portion and the corner region, the first integrated circuit unit is disposed on the flat portion, the second integrated circuit unit is disposed on the curved portion, and a size of the second integrated circuit unit is smaller than a size of the first integrated circuit unit.

17. The electronic device according to claim 10, wherein the flexible substrate comprises a plurality of main parts and a plurality of connection parts, at least one of the plurality of connection parts connects two adjacent main parts of the plurality of main parts, and one of the plurality of electronic components is disposed on one of the two adjacent main parts.

18. The electronic device according to claim 10, further comprising a supporting substrate disposed under the flexible substrate, wherein a portion of a bottom surface of the flexible substrate is exposed by the supporting substrate.

19. The electronic device according to claim 10, wherein the first integrated circuit unit comprises a semiconductor structure and a conductive structure, the conductive structure overlaps the semiconductor structure, and a material of the semiconductor structure comprises silicon carbide, silicon, germanium, gallium arsenide, indium phosphide, or gallium nitride.

20. The electronic device according to claim 10, wherein the first integrated circuit unit comprises:
a semiconductor structure;
a conductive structure overlapping the semiconductor structure; and
a packaging structure surrounding the semiconductor structure and the conductive structure.
